(19) United States
(12) Patent Application Publication
(10) Pub. No.: US 2010/0001402 A1
(43) Pub. Date: Jan. 7, 2010

(54) Multiple Patterning Method

(75) Inventor: Steffen Meyer, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/167,815

(22) Filed: Jul. 3, 2008

(51) Int. Cl. H01L 23/52; H01L 21/306

(52) U.S. Cl. 257/773; 438/705; 257/E23.141; 257/E21.219

(57) ABSTRACT

A self-aligned pitch fragmentation method for manufacturing an integrated circuit includes forming openings in a first layer, wherein the openings uncover first sections of a second layer arranged below the first layer. The first sections of the second layer are removed. The first layer is shrunk and the openings are expanded to form a first mask from the first layer, wherein the first mask exposes second sections and covers third sections of the second layer. The etch properties of the second sections are altered selectively to the third sections to facilitate the self-aligned pitch fragmentation method.

### BACKGROUND

During the fabrication of electronic devices a substrate and layers disposed over the substrate are patterned using lithography techniques, wherein both in the substrate and in individual ones of the layers line-shaped and/or dot-shaped features may be formed. Shrinking down the feature size to below the nominal resolution limit of the lithography exposure tool, double or multiple patterning techniques like pitch fragmentation, also known as pitch multiplication or self-aligned double patterning, and double exposure methods become of increasing interest.

According to conventional pitch fragmentation methods, a first pattern (e.g., a set of first lines) is formed. Along vertical sidewalls of the first lines, sidewall spacers are formed which do not fill completely the spaces between neighboring first lines. The remaining spaces may be filled and the sidewall spacers may be removed or the first lines may be removed selectively to the sidewall spacers in order to obtain a set of second lines which are spaced at the half pitch of the first lines, such that patterns with deep sub-lithographic features may be formed at a pitch which is smaller than the pitch which may be achieved using optical resolution enhancement techniques. For example, a pitch of less than 60 nm may be achieved using a 193 nanometer exposure tool. For forming a matrix of dot-shaped features, a mask may be formed by crossing line patterns formed in two layers arranged above each other, wherein at least one of the line patterns emerges from a pitch fragmentation method.

The formation of sidewall spacers is typically based on both a highly conformal film deposition and a precisely controlled anisotropic etch.

In light of deficiencies of the above discussed methods of forming regular sub-lithographic patterns, a need exists for improved methods of manufacturing dense patterns.

### SUMMARY

Described herein is an integrated circuit including first features of a first cross-section type and second features of a second, different cross-section type, which are arranged in equidistant rows and equidistant columns, respectively. The first and second features are arranged in accordance with a checkerboard pattern, such that individual ones of the first features are arranged in the center between four neighboring second features and individual ones of the second features are arranged in the center of four neighboring first features.

In addition, a self-aligned pitch fragmentation method for manufacturing an integrated circuit is described herein. The method includes forming openings in a first layer and removing exposed first sections of a second layer below the openings. The openings in the first layer are expanded to expose second sections of the second layer, whereas third sections of the second layer remain covered. The etch properties of the second sections may be altered selectively to the third sections. The method may, for example, facilitate a multiple pitch fragmentation without depositing a highly conformal layer and without etching a high-precision spacer.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of embodiments of the invention will be apparent from the following description of the drawings. The drawings are not necessarily to scale. Emphasis is placed upon illustrating the principles.

FIG. 1A illustrates a schematic cross sectional view of a portion of a substrate with a first layer comprising openings and exposing first sections of a second layer disposed below the first layer for illustrating a patterning method according to an embodiment.

FIG. 1B illustrates a schematic cross sectional view of the substrate portion of FIG. 1A after removing the first sections.

FIG. 1C illustrates a schematic cross sectional view of the substrate portion of FIG. 1B after shrinking the first layer and exposing second sections of the second layer.

FIG. 1D illustrates a schematic cross sectional view of the substrate portion of FIG. 1C after hardening the exposed second sections.

FIG. 1E illustrates a schematic cross sectional view of the substrate portion of FIG. 1D after removing third sections of the second layer.

FIG. 2A illustrates a schematic top view of a substrate portion with a first layer having line-shaped openings for illustrating a patterning method according to another embodiment.

FIG. 2B illustrates a schematic plan view of the substrate portion of FIG. 2A after removing sections of a second layer disposed below the first layer.

FIG. 3A illustrates a schematic plan view of a portion of another substrate with a first layer having dot-shaped openings for illustrating a patterning method in accordance with another embodiment.

FIG. 3B illustrates a schematic plan view of the substrate portion of FIG. 3A after removing sections of a second layer disposed below the first layer.

FIG. 4A illustrates a schematic cross sectional view of a portion of another substrate after patterning a resist layer disposed over a first layer for illustrating a patterning method in accordance with a further embodiment.

FIG. 4B illustrates a schematic cross sectional view of the substrate portion of FIG. 4A after exposing and removing first sections of a second layer disposed below the first layer.

FIG. 4C illustrates a schematic cross sectional view of the substrate portion of FIG. 4B after shrinking the first layer.

FIG. 4D illustrates a schematic cross sectional view of the substrate portion of FIG. 4C after exposing further sections of the second layer.

FIG. 4E illustrates a schematic cross sectional view of the substrate portion of FIG. 4D after removing further sections of the second layer.

FIG. 5A illustrates schematic cross sectional view of a contact matrix resulting from a patterning method according to embodiments of the invention.

FIG. 5B illustrates schematic cross sectional view of a capacitor matrix resulting from a patterning method according to other embodiments of the invention

FIG. 6A illustrates a simplified flow chart illustrating a method of manufacturing an integrated circuit in accordance with embodiments of the invention.

FIG. 6B illustrates a simplified flow chart illustrating a patterning method in accordance with other embodiments of the invention.

### DETAILED DESCRIPTION

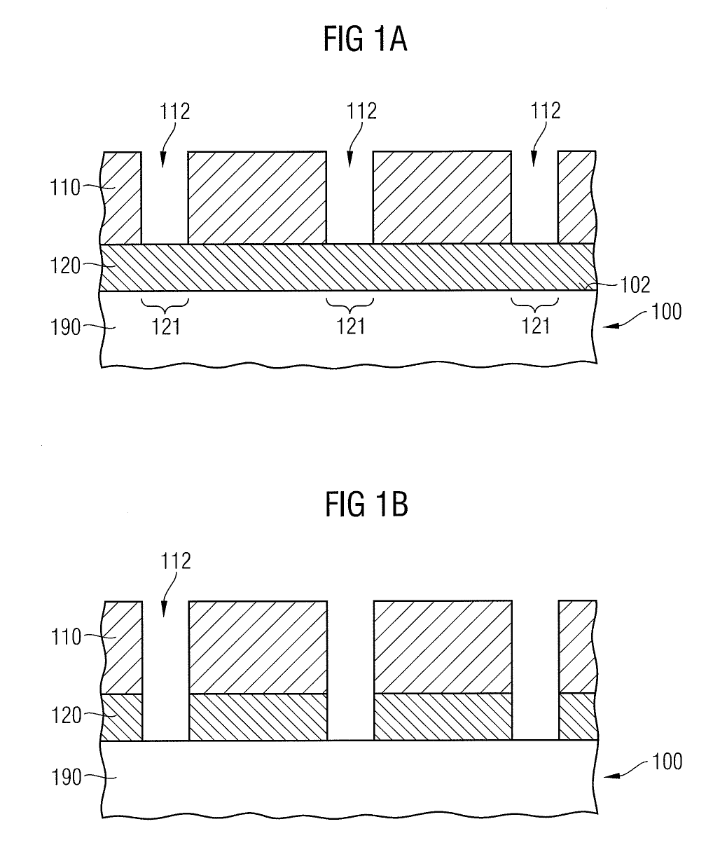

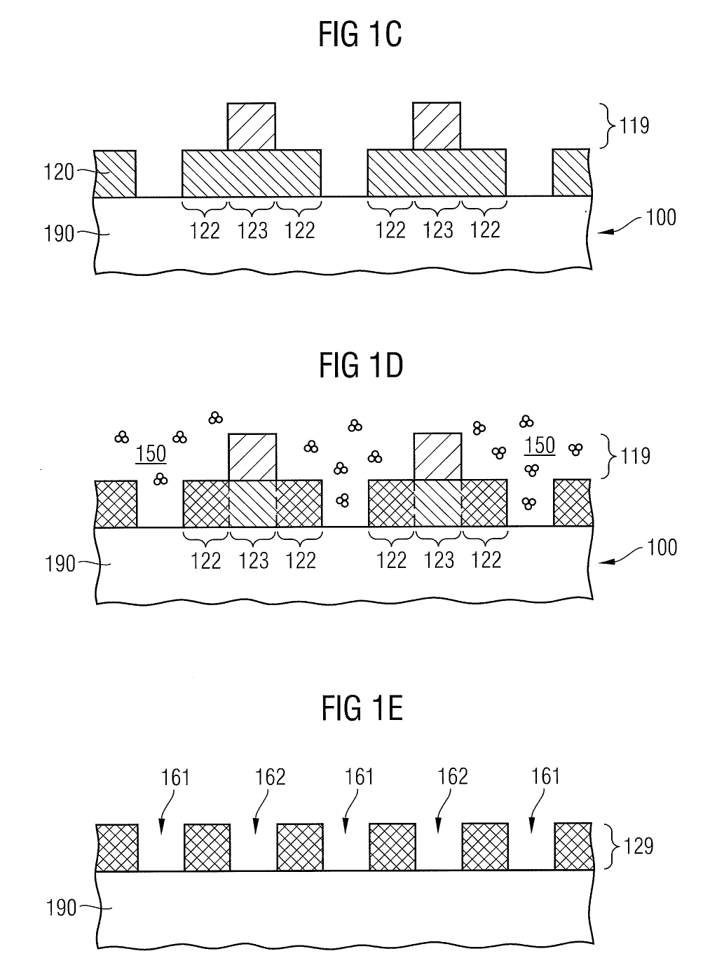

The described integrated circuit and self-aligned pitch fragmentation method are now described in further detail in relation to exemplary embodiments as depicted in FIGS. 1A-6B.

Referring to FIG. 1A, a layer stack including a first layer 110 and a second layer 120 is disposed on a main surface 102 of a substrate 100, wherein the first layer 110 is formed above the second layer 120. The substrate 100 may be a pre-processed workpiece, for example, a carrier consisting of or comprising glass or plastic, or a semiconductor wafer. According to an embodiment, the substrate 100 may be a singlecrystalline silicon wafer or a silicon-on-insulator wafer and may include further doped and undoped sections, epitaxial semiconductor layers as well as further conductive and insulating structures that have previously been fabricated. The main surface 102 is that surface of the substrate 100, which is subjected to the majority of patterning processes in course of the formation of integrated circuits from the substrate 100. A base layer 190 may form an upper section of the substrate 100 adjacent to the main surface 102. The materials of the first and the second layer 110, 120 may be selected such that a shrinkage or an isotropic recess of the first layer material has only little effect on the geometric dimensions of the second layer 120. The material of the first layer 110 may be, for example, carbon, an ARC-material (anti-reflective-coating), amorphous silicon, silicon nitride or a silicon oxide (e.g., silicon dioxide).

The material of the second layer 120 may be a material with image reversal capabilities such that its etch resistance is alterable, for example, through implant, radiation or chemical reaction with a fluid, wherein the material of the first layer 110 is capable of shielding covered sections of the second layer 120 against the implant, the radiation or the attack of the fluid. For example, the second layer 120 may be an amorphous silicon layer, the etch resistance of which may be altered by an implant using, for example, boron. According to another embodiment, the second layer 120 may be a silicon oxide or dioxide layer, the etch properties of which may be altered by nitriding or by implanting nitrogen or, a photosensitive layer like a resist material, the etch resistance of which may be altered by radiation, a polysilicon layer, the etch selectivity of which may be altered by a treatment in an ambient containing oxygen or nitrogen, or a hydrocarbon material, the etch properties of which may be altered by a chemical reaction.

FIG. 1A shows openings 112 formed in the first layer 110. The openings 112 uncover first sections 121 of the second layer 120. After the formation of the openings 112, the first sections 122 of the second layer 120 are exposed (i.e., uncovered), whereas the rest of the second layer 120 remains covered. According to further embodiments, an interface layer may be formed between the first and the second layers 110, 120. The openings 112 may be line-shaped openings or dot-shaped openings with circular or elliptic cross sections or with a rectangular cross section with rounded corners. The openings 112 may be formed via conventional lithography, via double exposure techniques or via pitch fragmentation methods.

Referring to FIG. 1B, the exposed first sections 121 of the second layer 120 may be removed, for example, by a suitable dry etch method (e.g., a reactive ion beam etch). Thereby, further openings are formed in the second layer 120.

As illustrated in FIG. 1C, the material of the first layer 110 may be shrunk or recessed isotropically, for example, using a suitable wet etch chemistry, an isotropic plasma etch or an anneal to widen the openings in the first layer 110. Shrinking of the first layer 110 exposes second sections 122 of the second layer 120 adjacent to the openings in the second layer 120. The shrunk material of the first layer 110 forms a first mask 119 that covers third sections 123 of the second layer 120 which may be spaced symmetrically from the openings in the second layer 120, and that exposes second sections 122 of the second layer 120.

Referring to FIG. 1D, the exposed second sections 122 of the second layer 120 may be hardened, for example, by exposure to a suitable radiation or a suitable fluid, or by a suitable implant. According to the illustrated embodiment, a fluid 150 is applied, a component of which reacts with the material of the second layer 120 to transform a first material of the second layer 120 in the exposed second sections 122 into a second material with an altered, for example, higher etch resistance. Due to the higher etch resistance in the exposed second sections 122, further sections of the second layer 120 may be etched selectively against the second sections 122, wherein the further sections are removed and the second sections 122 remain.

As illustrated in FIG. 1E, the first mask 119 may then be removed to expose the third sections 123. The exposed third sections 123 may be removed selectively to the second sections 122. The remaining second sections 123 of the second layer 120 form a patterned structure 129 that includes first openings 161 corresponding to the first sections 121 and second openings 162 corresponding to the third sections 123. The patterned structure 129 may be a final mold for forming vias, contacts or other devices in the first and second openings 161, 162. In accordance with other embodiments, the patterned structure 129 may form a second mask to form secondary openings in a layer or layer stack formed below the patterned structure 129. In accordance with other embodiments, those openings assigned to the first sections 121 may be refilled, for example, with the first material of the second layer 120, and the second sections 122 may be removed selectively to the filled first sections 121 and the third sections 123. In the embodiment as illustrated in FIG. 1E, the third sections 123 may be removed selectively to the second sections 122 to form a second mask 129 with line-shaped or dot-shaped openings arranged at half of the pitch of the openings 122 in the first layer 110 of FIG. 1A. The second mask 129 may be used as an etch mask, an implant mask or a block mask for the formation of structures in the substrate 100, for example, in the base layer 190, or as a template for the formation of a pattern above the base layer 190 in a damascene method, wherein the first and second openings 161, 162 are filled with a further material, which may be conductive. The second mask 129 may remain as a functional pattern, for example, as a dielectric fill, or may be removed after its use as mask or template.

According to a further embodiment, the first mask 119 is not removed completely but shrunk a second time to form a third mask exposing fourth sections and covering fifth sections of the second layer 120. The fourth sections may be removed selectively to the second sections 122. Then the third mask may be removed completely to expose the fifth sections, which may be hardened in a similar way as the second sections. Alternatively, the third mask may be shrunk another time to form a further mask exposing sixth sections, which may be hardened in a similar way as the second sections, and covering seventh sections, which may be removed selectively to the second and sixth sections after removal or a further shrink of the further mask. The procedure may be repeated further times to achieve multiple pitch fragmentation.

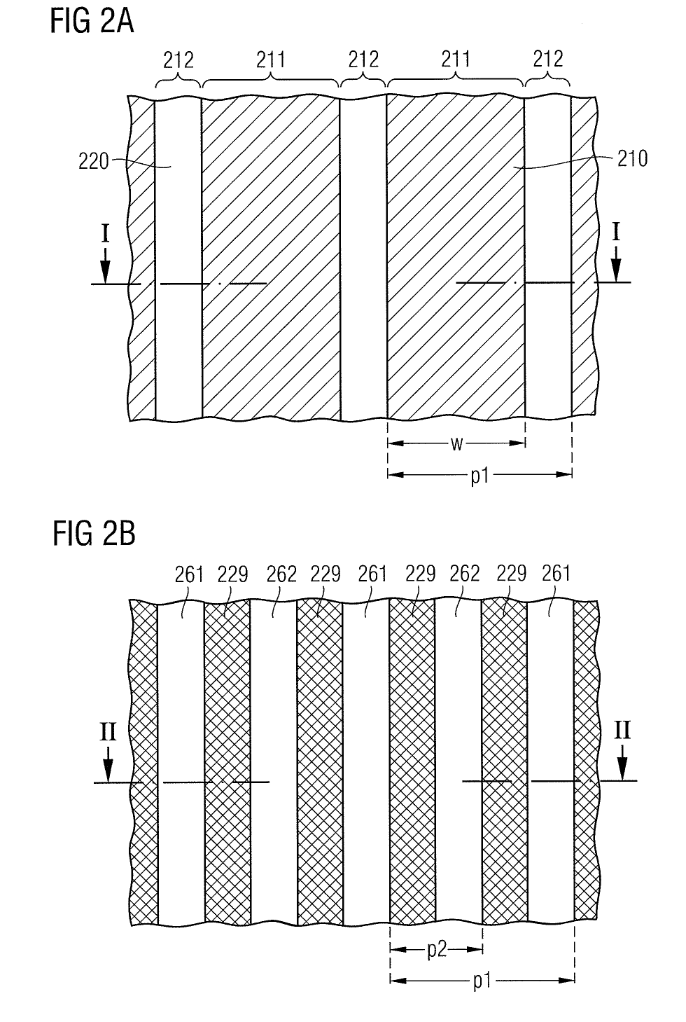

FIG. 2A shows a first layer 210 with line-shaped openings 212 between first mask lines 211, wherein the openings 212 expose sections of a second layer 220. The ratio of the width w of the first mask lines 211 to their pitch p1 may be about 0.75 as illustrated. According to other embodiments, the linewidth/pitch-ratio may be 0.5 such that the width of the openings 212 is approximately equal to the width w of the mask lines 211. According to an embodiment, the cross section I-I may correspond to the cross section as illustrated in FIG. 1A.

The plan view illustrated in FIG. 2B may correspond to the cross section illustrated in FIG. 1E and refers to a second mask with second mask lines 229 formed using the first mask lines 211 as illustrated in FIG. 2A and applying the method illustrated in FIGS. 1A-1E. First openings 261 between the second mask lines 229 correspond to the openings 212 of FIG. 2A while second openings 262 result from shrinking the mask lines 211 of FIG. 2A, hardening exposed second sections of the second layer 220, and removing third sections of the second layer 220, which are masked during the hardening treatment by shrunk portions of the first mask lines 211. The pitch p2 of the second mask lines 229 is half of the pitch p1 of the first mask lines 211. The embodiments facilitate pitch fragmentation without highly conformal layer deposition and without high-precision spacer etch. Though in the preceding Figures explained in detail with respect to regular patterns with repetitive structures in the first mask, further embodiments may refer to non-regular patterns with/or without non-repetitive structures in the first mask.

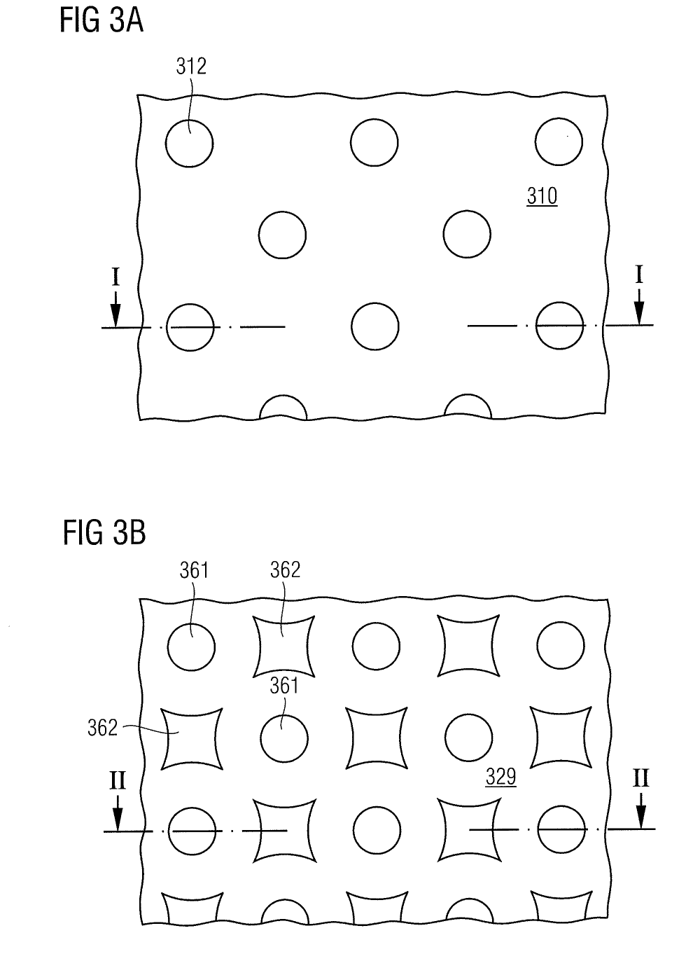

FIG. 3A refers to a regular dot matrix, for example for the formation of elements arranged in a two dimensional array, for example, an array of access transistors for storage elements (e.g., stack capacitors), or an array of dot-shaped gate electrodes of transistors arranged in a two dimensional matrix, or an array of openings in an etch mask for forming grooves in an underlying substrate or layer stack. In a first layer 310 dot-shaped openings 312 are formed that may be arranged in a regular, two dimensional matrix. According to other embodiments, one dimensional contact rows may be formed accordingly. In accordance with a further embodiment, the cross section I-I may correspond to the cross sectional view illustrated in FIG. 1A.

FIG. 3B illustrates a further plan view that may correspond to the cross section illustrated in FIG. 1E and shows a further second mask 329 formed using the patterned first layer 310 of FIG. 3A in accordance with the method illustrated in FIGS. 1A-1E. First openings 361 in the second mask 329 correspond to the openings 312 of FIG. 3A. Second openings 362 result from shrinking the patterned first layer 310 of FIG. 3A, wherein the second openings 362 are formed in the center between neighboring first openings 361. The shape of the second openings 362 may be rectified through further processes which may, for example, round the corners.

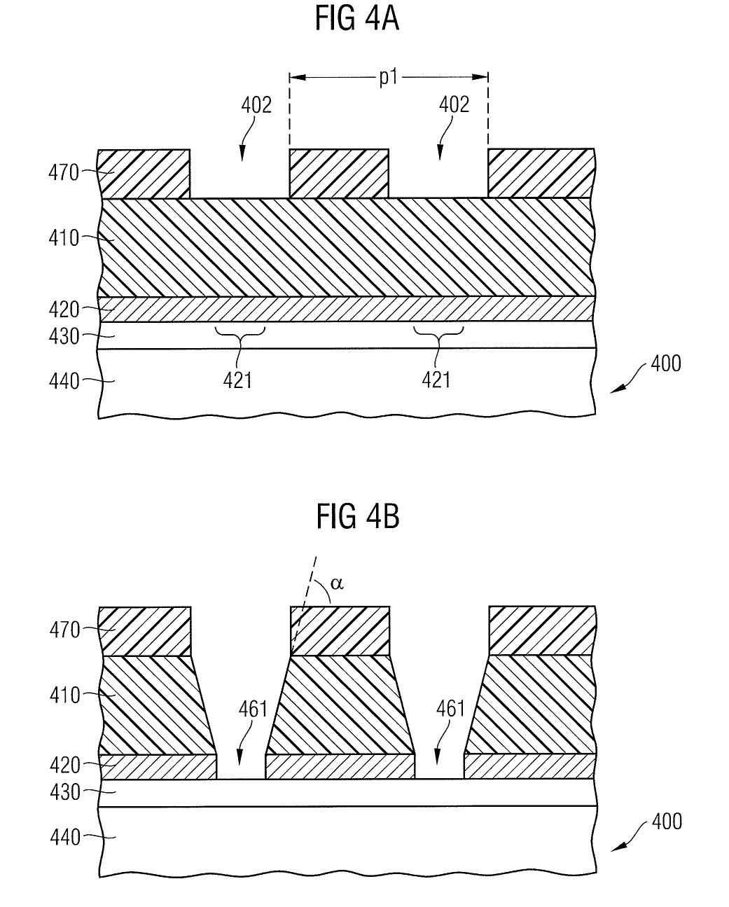

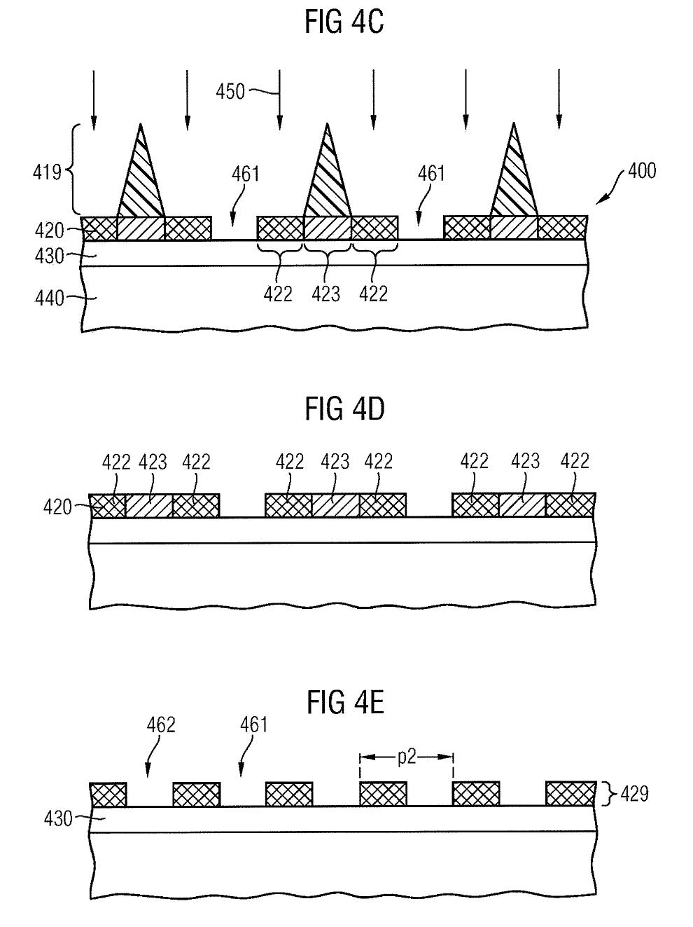

FIG. 4A refers to a method of patterning a final layer or layer stack 440 disposed above or in a substrate 400 using a spacerless self-aligned double patterning method in accordance with a further embodiment. The final layer or layer stack 440 may be a gate conductor stack, a metal stack, an interlevel dielectric, in which conductive vias are to be formed, a substrate, in which trench capacitors or other buried electronic devices are formed, or a hard mask. A stop layer 430, which may be a siliconoxynitride layer, may be deposited on the final layer or layer stack 440. The stop layer 430 may be a multiple layer stack which may be patterned in a previous process. On top of the stop layer 430, a second layer 420 with image reversal capabilities (e.g., amorphous silicon, silicon oxide, or a photosensitive material) may be deposited. A first layer 410 with isotropic shrinkage capabilities (e.g., a carbon layer, a BARC (bottom antireflective coating)-layer, an amorphous silicon layer, a silicon nitride layer or a silicon oxide layer) is deposited on top of the second layer 420. In accordance with other embodiments, an interface layer may be provided between the first and the second layer 410, 420. A photosensitive film (e.g., a resist) is deposited on the first layer 410 and patterned by conventional lithography to form a resist mask 470 with openings 402, which may be, for example, line-shaped or dot-shaped, and which are spaced at a pitch p1.

FIG. 4A shows the patterned resist mask 470 with openings 402 above first sections 421 in the second layer 420. The second layer 420 may be an amorphous silicon layer with a thickness equal to or smaller than about 50 nm, for example, equal to or smaller than about 30 nm. The stop layer 430, which may be a siliconoxynitride layer with a thickness equal to or smaller than about 50 nm (e.g., equal to or smaller than about 30 nm) is disposed between the second layer 420 and the final layer or layer stack 440, which is part of the substrate 400. The first layer 410 may be a BARC layer with a thickness of less than about 300 nm and more than about 100 nm.

Referring to FIG. 4B, the pattern of the resist mask 470 may be transferred into the first and the second layers 410, 420. The openings formed in the first layer 410 may taper toward the second layer 420, wherein a sidewall angle of the opening in the first layer 410 may be determined in dependence on the line/space-ratio in the resist mask 470. According to the illustrated embodiment, the line/space-ratio 470 is about 1:1 and the sidewall angle alpha is selected in dependence on the thickness of the first layer 410 such that the line/space-ratio in the second layer 420 is about 3:1. In accordance with another embodiment, an intermediate layer may be disposed between the resist layer forming the resist mask 470 and the first layer 410, wherein the intermediate layer is used to narrow the openings in the resist mask 470 at approximately a third such that the openings in the first layer 410 may be formed with approximately vertical sidewalls.

As illustrated in FIG. 4C, the resist mask 470 may be removed and the material of the first layer 410 may be shrunk, for example, through an isotropic etch, an anneal or a plasma etch in an oxygen containing ambient, to expand the openings in the first layer 410 and to form a first mask 419 resulting from the shrunk first layer 410. During the shrinkage, at least lateral dimensions of remnant portions of the first layer 410 are reduced compared with that of the corresponding portions before the shrinkage such that the shrinkage uncovers second sections 422 of the second layer 420 adjacent to the first openings 402. The remnant portions of the first layer 410 cover third sections 423; whereas the second sections 422 of the second layer 420 adjacent to the first openings 461 are exposed. An implant 450 may be performed to introduce impurities into the exposed second sections 422, wherein the etch properties of the exposed second sections 422 are altered. Due to the higher etch resistance in the exposed second sections 422, further sections of the second layer 420 may be etched selectively against the second sections 422, wherein the further sections are removed and the second sections 422 remain.

Referring to FIG. 4D the remnant portion of the first layer 410 forming the first mask 419 may be removed to expose the third sections 423, for example via a wet etch.

As illustrated in FIG. 4E, the third sections 423 may be removed selectively to the second sections 422 to form a patterned structure 429 with line-shaped or dot-shaped openings arranged at half of the pitch of the openings in the resist mask 470 of FIG. 4A. The remaining second sections 422 of the second layer 420 form the patterned structure 429 that includes first openings 461 corresponding to the first sections 421 and second openings 462 corresponding to the third sections 423. The patterned structure 429 may be used as an etch mask, an implant mask or a block mask for the formation of structures in the substrate 400, for example, in the final layer or layer stack 440, or as a template for the formation of a pattern above the stop layer 430 in a damascene method as discussed above with regard to FIG. 1E.

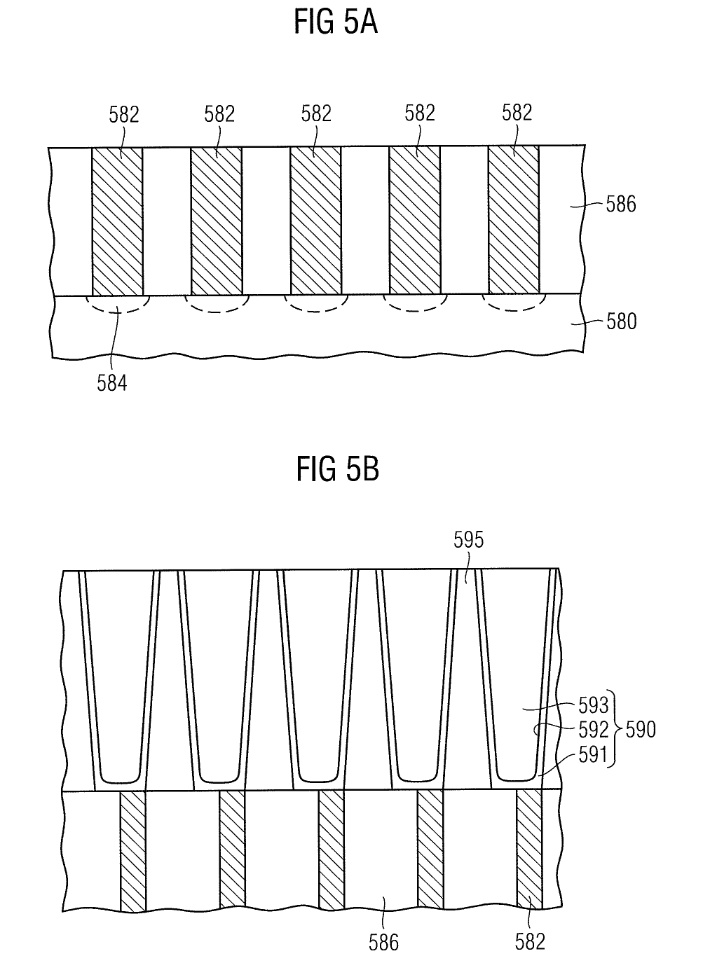

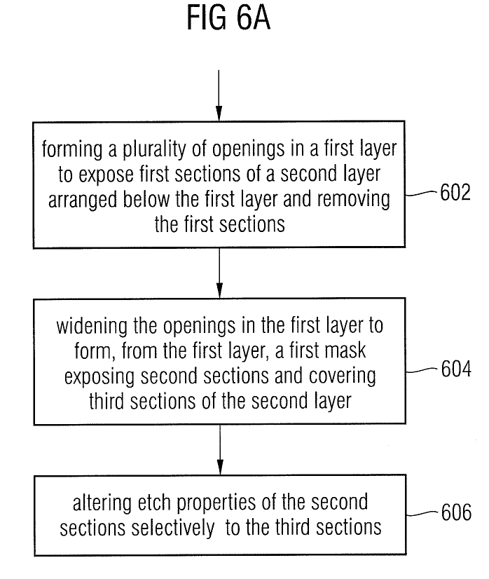

FIG. 5A is a cross section of a contact array formed in accordance with the method as described with reference to FIGS. 1A-1E or FIGS. 4A-4E. An array of conductive contact structures 582 may be formed in an interlevel dielectric 586. Each contact 582 may be in direct contact with a conductive structure 584, which may be, for example, an n-doped region 584 within an otherwise p-doped substrate 580.

FIG. 5B shows an array of contacts 582 connecting storage electrodes 591 of stack capacitors 590 to access transistors formed in a semiconductor substrate below the contacts 582. The stack capacitors 590 further comprise a backside electrode 593 and a capacitor dielectric 592 disposed between the storage electrode 591 and the backside electrode 593. The capacitors 590 are formed in a mold layer 595 comprising further portions of the backside electrode or an insulator material.

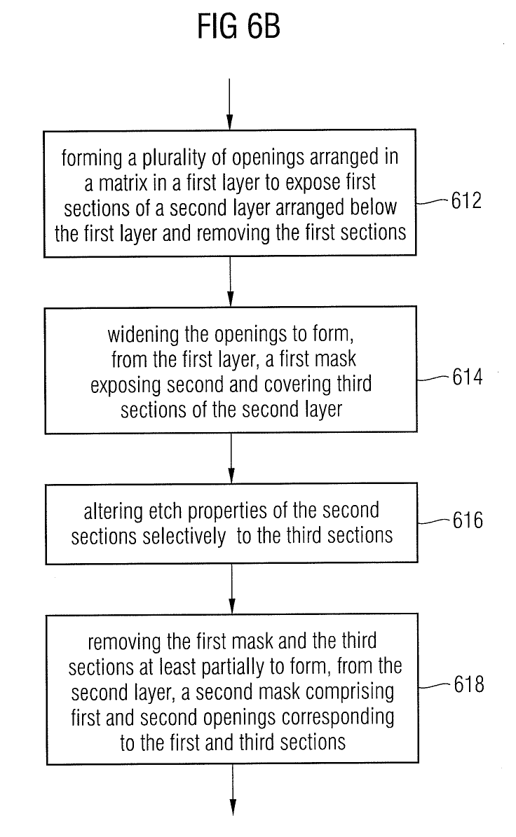

FIG. 6A is a simplified flow chart of a method of manufacturing an integrated circuit comprising a patterning method. A plurality of openings is formed in a first layer, wherein first sections of a second layer arranged below the first layer are exposed and the exposed first sections of the second layer are removed (602). The first layer is shrunk to expand the openings. A first mask is formed from the first layer, which exposes second sections and which covers third sections of the second layer (604). The etch properties of the second sections are altered selectively to the third sections (606) facilitating a spacerless, self-aligned pitch fragmentation method.

According to the simplified flow chart illustrated in FIG. 6B, a patterning method for manufacturing an integrated circuit includes the formation of a plurality of openings in a first layer. The openings may be arranged in a line/space-matrix or a dot-matrix and expose first sections of a second layer. The second layer is arranged below the first layer. The first sections of the second layer are removed (612). The openings are expanded, thereby forming a first mask from the first layer that exposes second sections and that covers third sections of the second layer (614). The etch properties of the second sections are altered selectively to that of the third sections (616). The first mask and the third sections are removed at least partially to form, from the second layer, a second mask that includes first and second openings corresponding to the first and third sections (618), wherein the pitch of the openings in the second layer is half of that of the openings in the first layer. The method facilitates, for example, the formation of line/space-patterns and dot-matrices with pitches significantly below the nominal optical resolution limit of the respective lithography system.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of manufacturing an integrated circuit, the method comprising:
forming openings in a first layer to expose first sections of a second layer, the second layer being arranged below the first layer;
removing the first sections;
expanding the openings in the first layer to form a first mask from the first layer, the first mask covering third sections of the second layer and leaving second sections of the second layer uncovered; and
altering etch properties of the second sections selectively to the third sections.

2. The method of claim 1, further comprising:
removing the first mask and the third sections to form, from the second layer, a patterned structure comprising first and second openings corresponding to the first and third sections.

3. The method of claim 1, wherein expanding the openings in the first layer comprises isotropically recessing the first layer.

4. The method of claim 1, wherein the first mask is removed and the third sections are removed via different etch chemistries.

5. The method of claim 1, wherein altering the etch properties comprises introducing impurities into the second sections.

6. The method of claim 1, wherein altering the etch properties comprises converting a first material of the second sections into a second material via a chemical reaction.

7. The method of claim 6, wherein the second sections are exposed to a fluid with a component which reacts with the first material.

8. The method of claim 6, wherein the second sections are exposed to a radiation which induces the chemical reaction.

9. The method of claim 1, further comprising:
forming secondary openings in a substrate beneath the patterned structure, wherein the patterned structure is an etch mask.

10. The method of claim 1, wherein the openings are line-shaped.

11. The method of claim 1, wherein the openings are dot-shaped.

12. A patterning method for manufacturing an integrated circuit, comprising:
forming a plurality of openings arranged in a matrix in a first layer to expose first sections of a second layer arranged below the first layer and removing the first sections;
widening the openings to form, from the first layer, a first mask exposing second sections and covering third sections of the second layer;
altering etch properties of the second sections selectively to the third sections; and
removing the first mask and the third sections at least partially to form, from the second layer, a patterned structure comprising first and second openings corresponding to the first and third sections of the second layer.

13. The method of claim 12, further comprising:
patterning and forming secondary openings in an insulator layer arranged below the patterned structure, wherein the patterned structure is an etch mask for patterning the insulator layer.

14. The method of claim 13, further comprising:
forming conductive contacts in the secondary openings.

15. The method of claim 13, further comprising:
forming capacitors in the secondary openings.

16. The method of claim 13, wherein the third sections are completely removed to form the patterned structure.

17. The method of claim 13, further comprising:
shrinking the first mask to form, from the first mask, a third mask exposing fourth sections and covering fifth sections of the second layer.

18. An integrated circuit, comprising:
a plurality of first features of a first cross-section type arranged in equidistant rows and equidistant columns;
a plurality of second features of a second cross-section type different from the first cross-section type arranged in equidistant rows and equidistant columns, the first and second features being arranged in accordance with a checkerboard pattern, wherein individual ones of the first features are arranged in the center between four of the second features and individual ones of the second features are arranged in the center of four neighboring first features.

19. The integrated circuit of claim 18, wherein the first and second features are conductive vias.

20. The integrated circuit of claim 18, wherein the first and second features have approximately the same planar cross-sectional area.

21. The integrated circuit of claim 18, wherein the first cross-section type is circular.

22. A method of manufacturing an integrated circuit, the method comprising:
forming openings in a first layer to uncover first portions of a second layer arranged below the first layer;
removing the uncovered first portions;
widening the openings in the first layer to uncover second portions of the second layer; and
altering the etch properties of the uncovered second portions.

23. The method of claim 22, further comprising:
removing remnant portions of the first layer and third portions of the second layer, wherein the remnant portions of the first layer cover the third portions of the second layer after widening the openings in the first layer, the patterned structure comprising first and second openings corresponding to the first and third portions of the second layer.

24. The method of claim 22, further comprising:
forming secondary openings in a carrier beneath the patterned structure, wherein the patterned structure is an etch mask for forming the secondary openings.
